(19) United States
(12) Patent Application Publication
(10) Pub. No.: US 2014/0239229 A1
(43) Pub. Date: Aug. 28, 2014

(54) ORGANIC ELECTROLUMINESCENCE MATERIAL AND ORGANIC ELECTROLUMINESCENCE DEVICE INCLUDING THE SAME

(71) Applicant: Samsung Display Co., Ltd., Yongin-City (KR)

(72) Inventors: Nobutaka AKASHI, Yokohama (JP); Toshiaki MURAI, Yokohama (JP)

(73) Assignee: SAMSUNG DISPLAY CO., LTD., Yongin-City (KR)

(21) Appl. No.: 14/189,422

(22) Filed: Feb. 25, 2014

(30) Foreign Application Priority Data
Feb. 28, 2013 (JP) 2013-039743

(51) Int. Cl. H01L 51/00

(52) U.S. Cl. CPC H01L 51/0069
USPC 252/301.16; 548/190

(57) ABSTRACT

An organic electroluminescence (EL) device comprising an organic EL material represented by the following Formula (1):

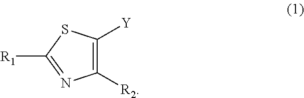

### CROSS-REFERENCE TO RELATED APPLICATION

Japanese Patent Application No. 2013-039743, filed on Feb. 28, 2013, in the Japanese Patent Office, is incorporated by reference in its entirety.

### BACKGROUND

1. Field

Embodiments relate to an organic electroluminescence material and an organic electroluminescence device including the same.

2. Description of the Related Art

Organic electroluminescence (EL) display devices (that are one type of image display devices) have been actively developed. Unlike a liquid crystal display device and the like, the organic EL display device is a so-called a self-luminescent display device that recombines holes and electrons injected from a positive electrode and a negative electrode in an emission layer to thus emit a light from a light-emitting material (including an organic compound of the emission layer), thereby performing display.

An example of a light-emitting device (hereinafter referred to as an organic EL device) may include an organic EL device that includes a positive electrode, a hole transport layer on the positive electrode, an emission layer on the hole transport layer, an electron transport layer on the emission layer, and a negative electrode on the electron transport layer. Holes injected from the positive electrode may be injected into the emission layer via the hole transport layer. Meanwhile, electrons may be injected from the negative electrode, and then injected into the emission layer via the electron transport layer. The holes and the electrons injected into the emission layer may be recombined to generate excitons within the emission layer. The organic EL device may emit light by using a light generated by radiation and deactivation of the excitons. Also, the organic EL device is not limited to the above-described configuration but may be changed in various forms.

### SUMMARY

Embodiments are directed to an organic electroluminescence material and an organic electroluminescence device including the same.

The embodiments may be realized by providing an organic electroluminescence (EL) device comprising an organic EL material represented by the following Formula (1):

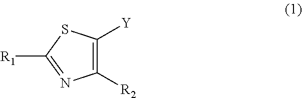

wherein R₁ is selected from the group of a branched or cyclic alkyl group having 3 to 20 carbon atoms, an aryl group having 6 to 24 carbon atoms, and a heteroaryl group having 6 to 24 carbon atoms, each being unsubstituted or substituted with at least one substituent selected from the group of a halogen atom, a hydroxyl group, a lower alkyl group, a lower alkoxy group, and a lower haloalkyl group, R₂ is a substituted or unsubstituted aryl group or a substituted or unsubstituted heteroaryl group, the substituted aryl group or substituted heteroaryl group being substituted with at least one substituent selected from the group of a halogen atom, a hydroxyl group, a lower alkyl group, a lower alkoxy group, and a lower haloalkyl group, and Y is a substituent represented by the following Formula (2),

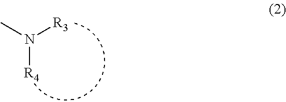

wherein, in Formula 2, R₃ and R₄ are each independently selected from the group of a linear or branched alkyl group having 1 to 20 carbon atoms, a cyclic alkyl group having 3 to 20 carbon atoms, an aryl group having 6 to 24 carbon atoms, and a heteroaryl group having 6 to 24 carbon atoms, each being unsubstituted or substituted with at least one substituent selected from the group of a halogen atom, a hydroxyl group, a lower alkyl group, a lower alkoxy group, a lower haloalkyl group, an aryl group, and a heteroaryl group.

R₃ and R₄ may be bound together and form a heterocycle with a nitrogen atom (N) in the substituent represented by Formula (2).

R₃ and R₄ may be separate from one another.

The organic EL material represented by above Formula (1) may be a light-emitting material of the organic EL device.

The light-emitting material may be a blue light-emitting material.

The light-emitting material may be included in an emission layer along with a condensed polycyclic hydrocarbon derivative.

The condensed polycyclic hydrocarbon derivative may be one of a substituted or unsubstituted naphthalene derivative, a substituted or unsubstituted anthracene derivative, a substituted or unsubstituted phenanthrene derivative, a substituted or unsubstituted pyrene derivative, a substituted or unsubstituted triphenylene derivative, a substituted or unsubstituted chrysene derivative, a substituted or unsubstituted perylene derivative, or a substituted or unsubstituted fluorene derivative.

The condensed polycyclic hydrocarbon derivative may be the substituted or unsubstituted anthracene derivative or the substituted or unsubstituted pyrene derivative.

The condensed polycyclic hydrocarbon derivative may be a host and the organic EL material represented by the above Formula (1) may be a dopant.

### BRIEF DESCRIPTION OF THE DRAWING

Features will be apparent to those of skill in the art by describing in detail exemplary embodiments with reference to the attached drawing in which:

FIG. 1 illustrates a schematic diagram of the structure of an organic EL device.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figure, the dimensions of layers and regions may be exaggerated for clarity of illustration. Like reference numerals refer to like elements throughout.

A 5-aminothiazole derivative may be used as a blue light-emitting material in the emission layer of an organic EL device. Light-emitting efficiency of the organic EL device may thus be improved. The embodiments may provide an organic EL material including the 5-aminothiazole derivative and an organic EL device using the same.

The 5-aminothiazole derivative used as, e.g., the blue light-emitting organic material, may be represented by Formula (1), below.

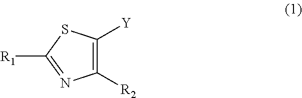

In Formula (1), R₁ may be selected from the group of a branched or cyclic alkyl group having 3 to 20 carbon atoms, an aryl group having 6 to 24 carbon atoms, and a heteroaryl group having 6 to 24 carbon atoms. Each of the alkyl group, the aryl group, or the heteroaryl group may be unsubstituted or substituted with at least one substituent selected from the group of a halogen atom, a hydroxyl group, a lower alkyl group, a lower alkoxy group, and a lower haloalkyl group.

R₂ may be a substituted or unsubstituted aryl group or a substituted or unsubstituted heteroaryl group. In an implementation, R₂ may be a substituted or unsubstituted aryl group having 6 to 24 carbon atoms or a substituted or unsubstituted heteroaryl group having 6 to 24 carbon atoms. The substituted aryl group or the substituted heteroaryl group may be substituted with at least one substituent selected from the group of a halogen atom, a hydroxyl group, a lower alkyl group, a lower alkoxy group, and a lower haloalkyl group.

Y may be a substituent represented by Formula (2), below.

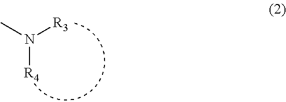

In Formula (2), R₃ and R₄ may each independently be selected from the group of a linear or branched alkyl group having 1 to 20 carbon atoms, a cyclic alkyl group having 3 to 20 carbon atoms, an aryl group having 6 to 24 carbon atoms, and a heteroaryl group having 6 to 24 carbon atoms. Each of the alkyl group, the cyclic alkyl group, the aryl group, or the heteroaryl group may be unsubstituted or substituted with at least one substituent selected from the group of a halogen atom, a hydroxyl group, a lower alkyl group, a lower alkoxy group, a lower haloalkyl group, an aryl group and a heteroaryl group. In an implementation, in Formula (2), R₃ and R₄ may combine or be bound together, and may form a heterocycle with a nitrogen atom (N) that makes chemical bonds with R₃ and R₄ (e.g., as shown by the dashed line in Formula (2)). In an implementation, R₃ and R₄ may be separate from one another.

Examples of the 5-aminothiazole derivatives applicable as the blue light-emitting organic material according to an embodiment may include compounds 1 to 42, below.

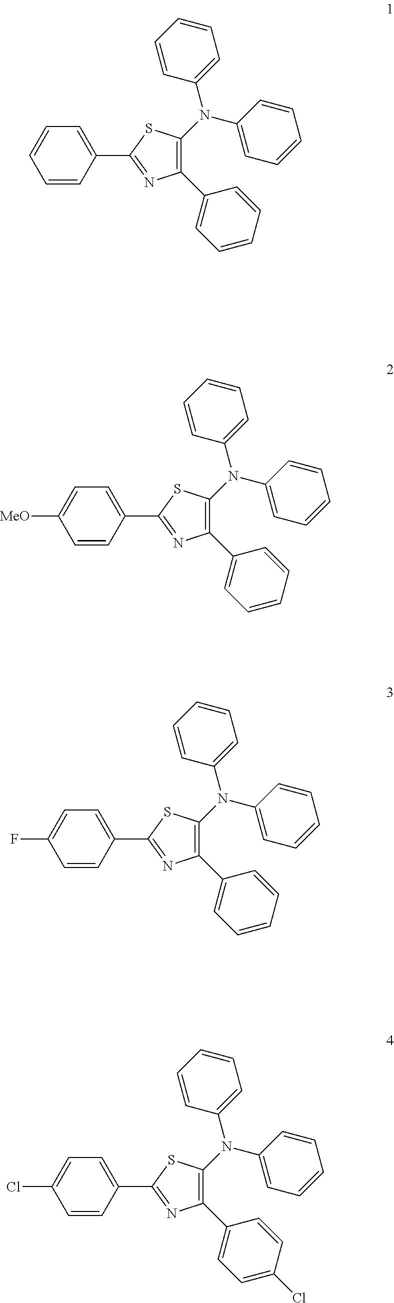 [SMILES: c1ccc(-c2nc(-c3ccccc3)c(N(c3ccccc3)c3ccccc3)s2)cc1 ; COc1ccc(-c2nc(-c3ccccc3)c(N(c3ccccc3)c3ccccc3)s2)cc1 ; Fc1ccc(-c2nc(-c3ccccc3)c(N(c3ccccc3)c3ccccc3)s2)cc1 ; Clc1ccc(-c2nc(-c3ccc(Cl)cc3)c(N(c3ccccc3)c3ccccc3)s2)cc1]

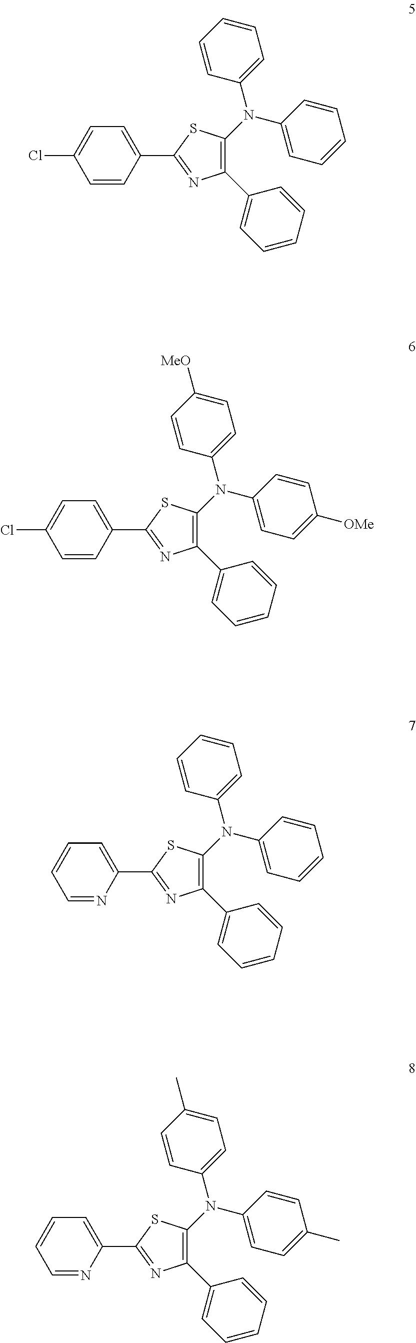 [SMILES: Clc1ccc(-c2nc(-c3ccccc3)c(N(c3ccccc3)c3ccccc3)s2)cc1 ; COc1ccc(N(c2ccc(OC)cc2)c2sc(-c3ccc(Cl)cc3)nc2-c2ccccc2)cc1 ; c1ccc(-c2nc(-c3ccccn3)sc2N(c2ccccc2)c2ccccc2)cc1 ; Cc1ccc(N(c2ccc(C)cc2)c2sc(-c3ccccn3)nc2-c2ccccc2)cc1]

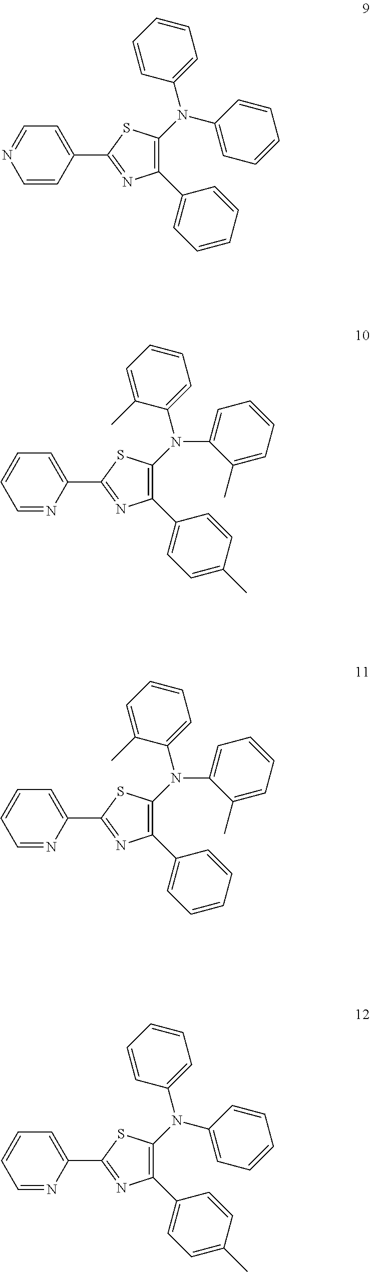 [SMILES: c1ccc(-c2nc(-c3ccncc3)sc2N(c2ccccc2)c2ccccc2)cc1 ; Cc1ccc(-c2nc(-c3ccccn3)sc2N(c2ccccc2C)c2ccccc2C)cc1 ; Cc1ccccc1N(c1ccccc1C)c1sc(-c2ccccn2)nc1-c1ccccc1 ; Cc1ccc(-c2nc(-c3ccccn3)sc2N(c2ccccc2)c2ccccc2)cc1]

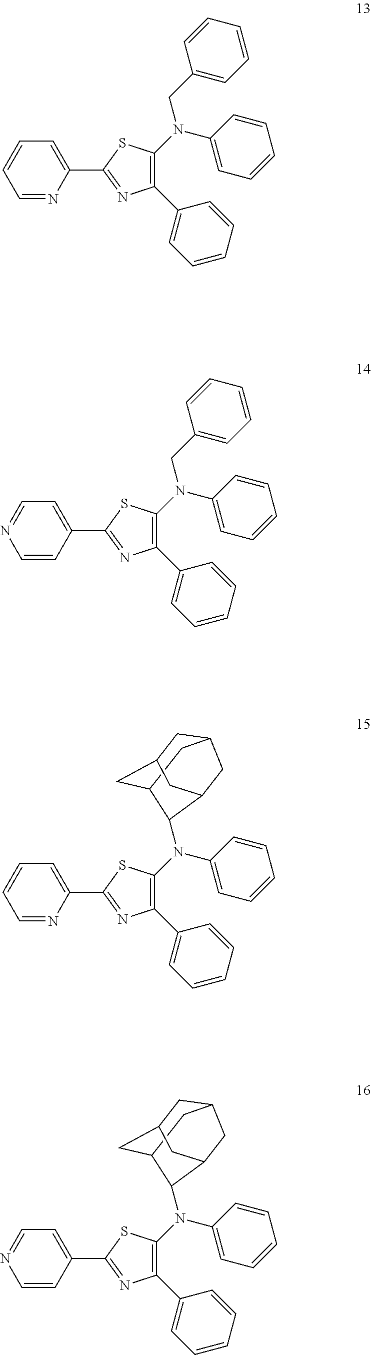 [SMILES: c1ccc(CN(c2ccccc2)c2sc(-c3ccccn3)nc2-c2ccccc2)cc1 ; c1ccc(CN(c2ccccc2)c2sc(-c3ccncc3)nc2-c2ccccc2)cc1 ; c1ccc(-c2nc(-c3ccccn3)sc2N(c2ccccc2)C2C3CC4CC(C3)CC2C4)cc1 ; c1ccc(-c2nc(-c3ccncc3)sc2N(c2ccccc2)C2C3CC4CC(C3)CC2C4)cc1]

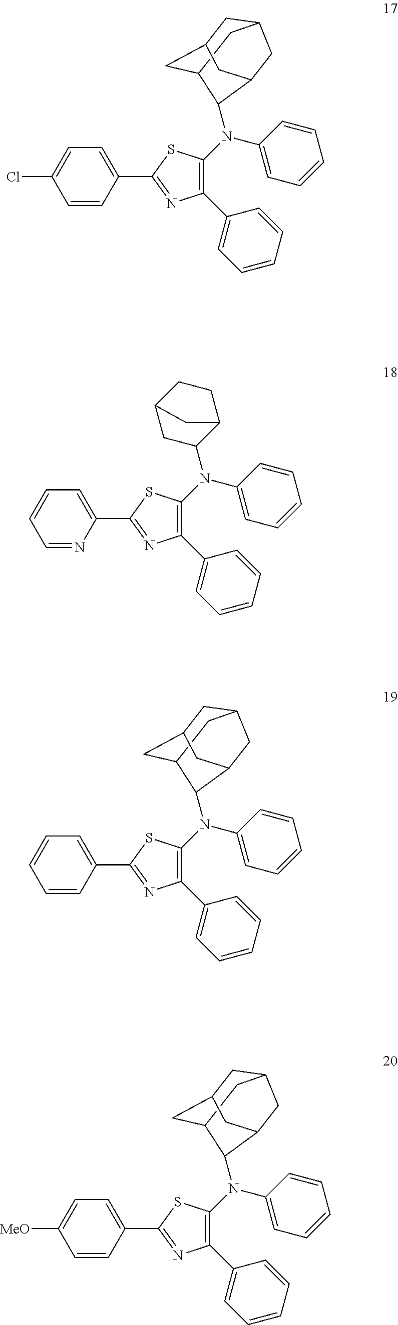 [SMILES: Clc1ccc(-c2nc(-c3ccccc3)c(N(c3ccccc3)C3C4CC5CC(C4)CC3C5)s2)cc1 ; c1ccc(-c2nc(-c3ccccn3)sc2N(c2ccccc2)C2CC3CCC2C3)cc1 ; c1ccc(-c2nc(-c3ccccc3)c(N(c3ccccc3)C3C4CC5CC(C4)CC3C5)s2)cc1 ; COc1ccc(-c2nc(-c3ccccc3)c(N(c3ccccc3)C3C4CC5CC(C4)CC3C5)s2)cc1]

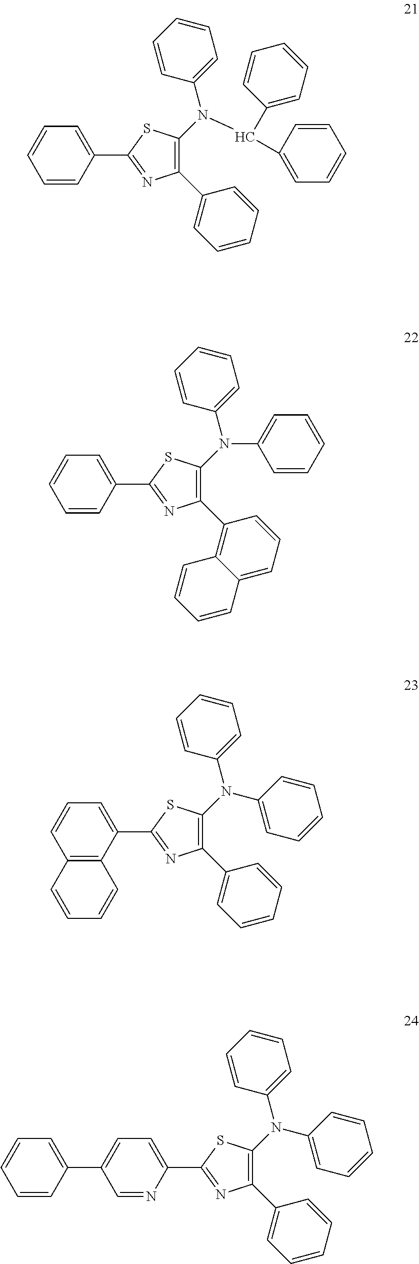 [SMILES: c1ccc(-c2nc(-c3ccccc3)c(N(c3ccccc3)C(c3ccccc3)c3ccccc3)s2)cc1 ; c1ccc(-c2nc(-c3cccc4ccccc34)c(N(c3ccccc3)c3ccccc3)s2)cc1 ; c1ccc(-c2nc(-c3cccc4ccccc34)sc2N(c2ccccc2)c2ccccc2)cc1 ; c1ccc(-c2ccc(-c3nc(-c4ccccc4)c(N(c4ccccc4)c4ccccc4)s3)nc2)cc1]

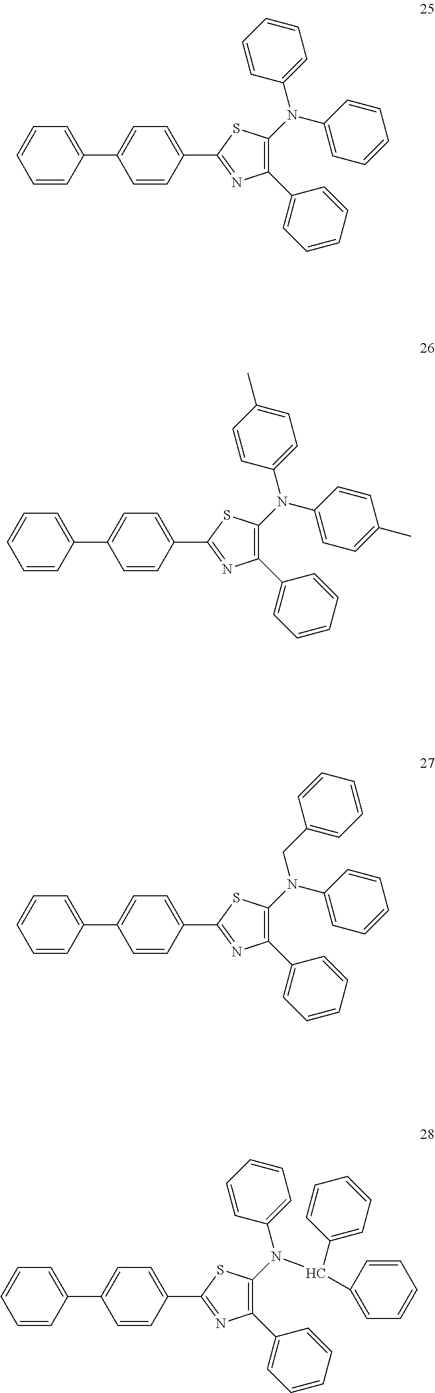 [SMILES: c1ccc(-c2ccc(-c3nc(-c4ccccc4)c(N(c4ccccc4)c4ccccc4)s3)cc2)cc1 ; Cc1ccc(N(c2ccc(C)cc2)c2sc(-c3ccc(-c4ccccc4)cc3)nc2-c2ccccc2)cc1 ; c1ccc(CN(c2ccccc2)c2sc(-c3ccc(-c4ccccc4)cc3)nc2-c2ccccc2)cc1 ; c1ccc(-c2ccc(-c3nc(-c4ccccc4)c(N(c4ccccc4)C(c4ccccc4)c4ccccc4)s3)cc2)cc1]

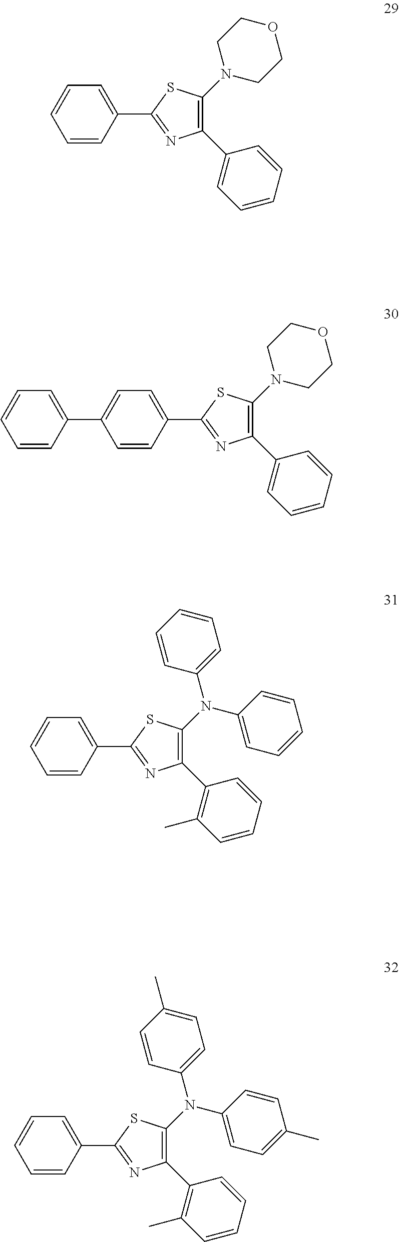 [SMILES: c1ccc(-c2nc(-c3ccccc3)c(N3CCOCC3)s2)cc1 ; c1ccc(-c2ccc(-c3nc(-c4ccccc4)c(N4CCOCC4)s3)cc2)cc1 ; Cc1ccccc1-c1nc(-c2ccccc2)sc1N(c1ccccc1)c1ccccc1 ; Cc1ccc(N(c2ccc(C)cc2)c2sc(-c3ccccc3)nc2-c2ccccc2C)cc1]

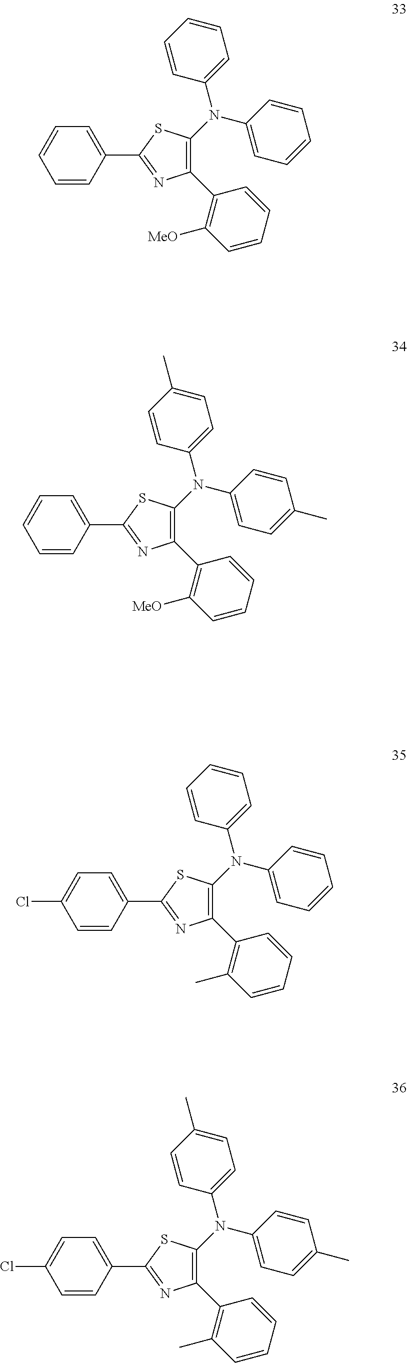 [SMILES: COc1ccccc1-c1nc(-c2ccccc2)sc1N(c1ccccc1)c1ccccc1 ; COc1ccccc1-c1nc(-c2ccccc2)sc1N(c1ccc(C)cc1)c1ccc(C)cc1 ; Cc1ccccc1-c1nc(-c2ccc(Cl)cc2)sc1N(c1ccccc1)c1ccccc1 ; Cc1ccc(N(c2ccc(C)cc2)c2sc(-c3ccc(Cl)cc3)nc2-c2ccccc2C)cc1]

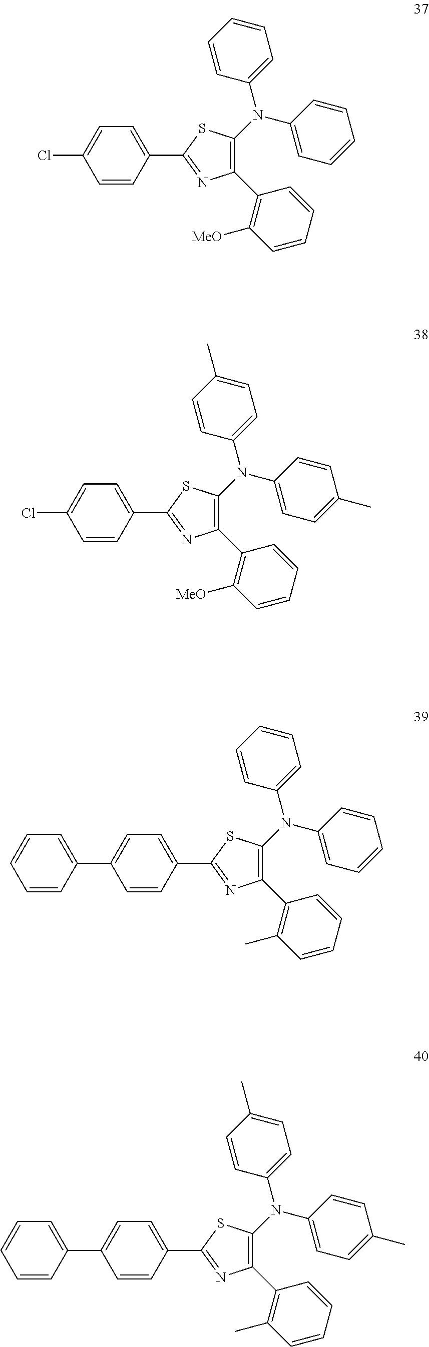 [SMILES: COc1ccccc1-c1nc(-c2ccc(Cl)cc2)sc1N(c1ccccc1)c1ccccc1 ; COc1ccccc1-c1nc(-c2ccc(Cl)cc2)sc1N(c1ccc(C)cc1)c1ccc(C)cc1 ; Cc1ccccc1-c1nc(-c2ccc(-c3ccccc3)cc2)sc1N(c1ccccc1)c1ccccc1 ; Cc1ccc(N(c2ccc(C)cc2)c2sc(-c3ccc(-c4ccccc4)cc3)nc2-c2ccccc2C)cc1]

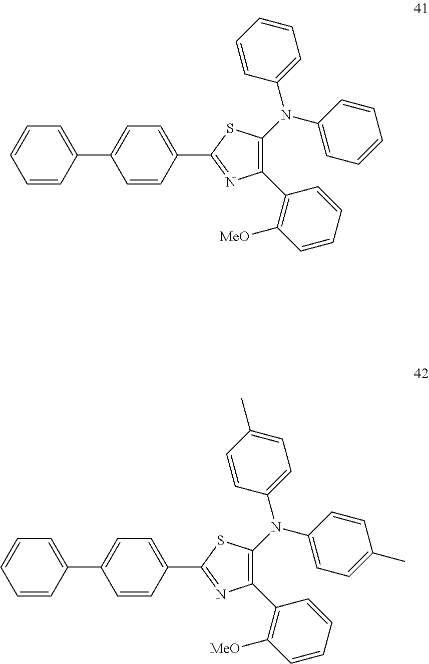 [SMILES: COc1ccccc1-c1nc(-c2ccc(-c3ccccc3)cc2)sc1N(c1ccccc1)c1ccccc1 ; COc1ccccc1-c1nc(-c2ccc(-c3ccccc3)cc2)sc1N(c1ccc(C)cc1)c1ccc(C)cc1]

As described above, the 5-aminothiazole derivative according to an embodiment may be used as the blue light-emitting organic material. For example, the 5-aminothiazole derivative according to an embodiment may be used as a dopant material included in a host material, thereby realizing the high efficiency of an organic EL device. The host material may be, e.g., a condensed polycyclic hydrocarbon derivative. In an implementation, the host material may include, e.g., a substituted or unsubstituted naphthalene derivative, a substituted or unsubstituted anthracene derivative, a substituted or unsubstituted phenanthrene derivative, a substituted or unsubstituted pyrene derivative, a substituted or unsubstituted triphenylene derivative, a substituted or unsubstituted chrysene derivative, a substituted or unsubstituted perylene derivative, a substituted or unsubstituted fluorene derivative, or the like. In an implementation, host material may include, e.g., the substituted or unsubstituted anthracene derivative or the substituted or unsubstituted pyrene derivative.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

Hereinafter synthetic methods of preparing Compound 1, Compound 5, Compound 7, Compound 9, Compound 14, Compound 22, Compound 23, Compound 24, and Compound 25 as the 5-aminothiazole derivatives of an embodiment will be explained referring to the following Reaction Schemes 12 to 15.

### Synthesis of Compound 1

### Synthesis of Intermediate 1 (N-phenylmethylbenzenecarbothioamide)

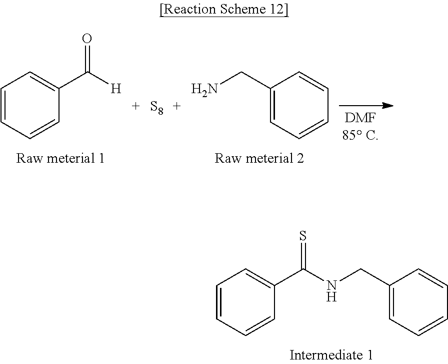

Benzaldehyde (10.1 mL, 0.1 mol) as Raw material 1 was added to benzylamine (12.0 mL, 0.11 mol) as Raw material 2 in dimethylformamide (DMF, 50 mL) at room temperature. Then, sulfur (3.52 g, 0.11 mol) was added and heated to 80 to 90° C. and stirred for 6 hours. The reaction mixture was poured into ethyl ether (50 mL), and an organic phase was washed using a saturated aqueous sodium hydrogen carbonate solution (200 mL), and hydrochloric acid (35%, 10 mL). An organic phase was dried using magnesium sulfate, filtered, and condensed under a reduced pressure. The residue thus obtained was recrystallized using hexane/methylene chloride (1:1, 30 mL) to obtain 21.3 g of Intermediate 1 as a yellow solid (yield 94%).

### Synthesis of Intermediate 2

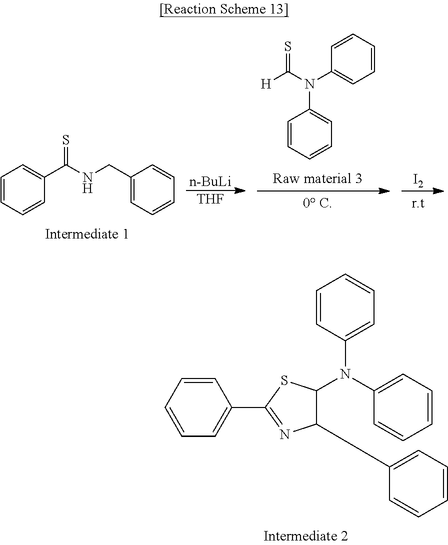

Intermediate 1 (0.257 g, 1.0 mmol) was dissolved in tetrahydrofuran (THF, 2.0 mL), and n-BuLi in hexane solution (1.43 M, 1.40 mL, 2.0 mmol) was added at 0° C. The reaction mixture was stirred for 5 minutes. Into the reaction mixture, N,N-diphenylthioformamide (0.213 g, 1.0 mmol) as raw material 3 was added at 0° C. and stirred for 30 minutes. Then, iodine (0.512 g, 2.0 mmol) was added at 0° C. and the stirring was continued for 2 hours. The reaction mixture was poured into a saturated ammonium chloride solution, and extraction was performed using methylene chloride. An organic phase was dried using magnesium sulfate and condensed. The residue thus obtained was purified by using a silica gel column chromatography to obtain a compound corresponding to Intermediate 2 with the yield of 26% as a yellow solid.

### Synthesis of Compound 1

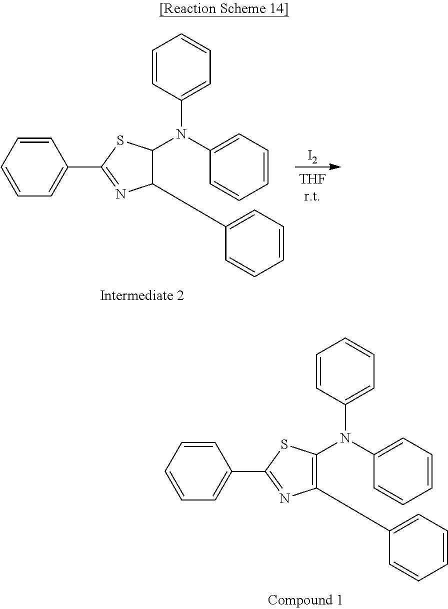

Intermediate 2 was dissolved in THF (1.1 mL), and iodine was added at room temperature. The extinction of the starting material was checked by using thin layer chromatography (TLC) while performing the reaction. After 24 hours, almost all of the starting material was disappeared, and common post-treatments were performed. As the result, Compound 1 was obtained with the yield of 99%.

Compound 5, Compound 7, Compound 9, Compound 14, Compound 22, Compound 23, Compound 24, and Compound 25 were synthesized by performing similar synthetic methods as that of Compound 1, as illustrated below.

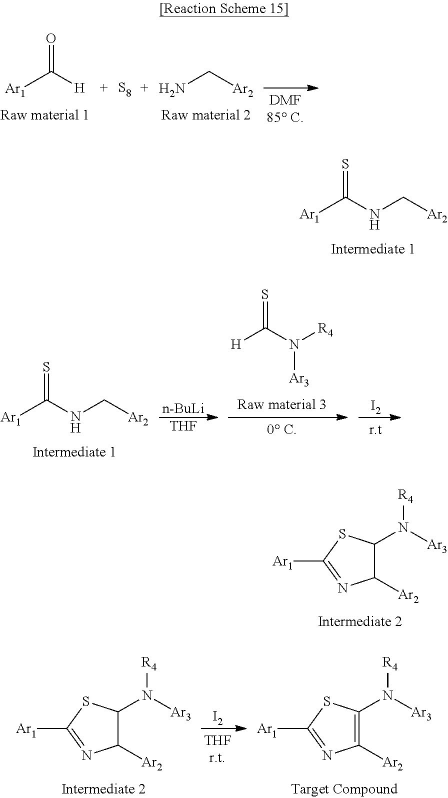

Raw material 1, Raw material 2, and Raw material 3 (in which Ar₁, Ar₂, Ar₃, and Ar₄ in the structures of the above-described Raw material 1, Raw material 2, and Raw material 3 are the substituents shown in the following Table 1), were prepared. Under the same synthetic conditions as that of the above-described Compound 1, Compound 5, Compound 7, Compound 9, Compound 14, Compound 22, Compound 23, Compound 24, and Compound 25 were synthesized.

TABLE 1

| Compound | Ar₁ | Ar₂ | Ar₃ | Ar₄ | Yield(%) |
|---|---|---|---|---|---|
| Compound 1 | 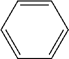 | 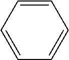 | 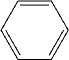 | 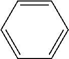 | 99 |
| Compound 5 | 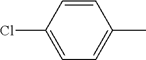 | 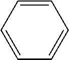 | 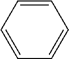 | 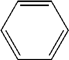 | 96 |
| Compound 7 | 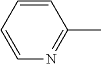 | 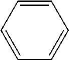 | 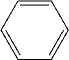 | 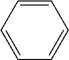 | 48 |
| Compound 9 | 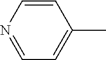 | 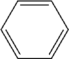 | 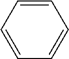 | 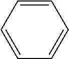 | 26 |
| Compound 14 | 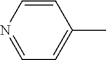 | 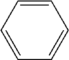 | 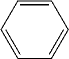 | 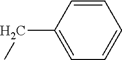 | 45 |
| Compound 22 | 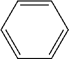 | 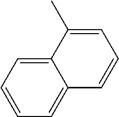 | 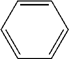 | 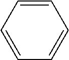 | 57 |
| Compound 23 | 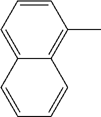 | 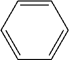 | 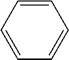 | 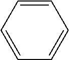 | 38 |
| Compound 24 | 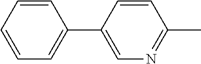 | 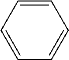 | 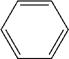 | 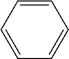 | 43 |
| Compound 25 | 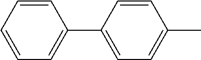 | 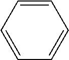 | 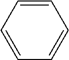 | 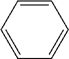 | 32 |

### Experimental

The current efficiency of an organic EL device using the 5-aminothiazole derivative of the embodiments as the blue light-emitting material (dopant material) of the emission layer of the organic EL device was measured. The light-emitting materials used in the emission layer of the organic EL device were Compound 1, Compound 5, Compound 7, Compound 9, Compound 14, Compound 22, Compound 23, Compound 24, and Compound 25. In addition, as a comparative compound, 6,12-bis(diphenylamino)chrysene was used as the light-emitting material (dopant).

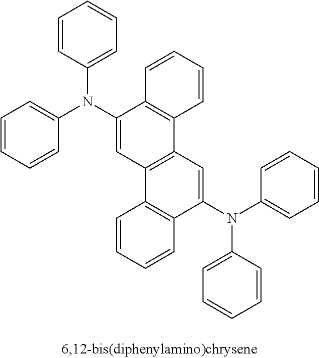 [SMILES: c1ccc(N(c2ccccc2)c2cc3c4ccccc4c(N(c4ccccc4)c4ccccc4)cc3c3ccccc23)cc1]

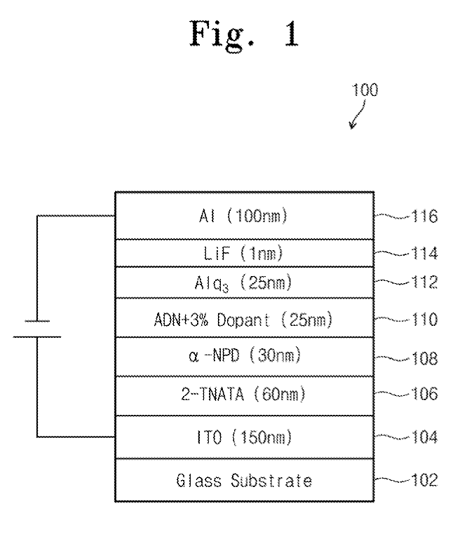

The constitution of the organic EL device used for the measurement is illustrated in FIG. 1. As illustrated in FIG. 1, the organic EL device 100 included a glass substrate 102, a positive electrode 104 on the glass substrate 102 (formed using indium tin oxide (ITO)), a hole injection layer 106 on the positive electrode 104 (including 4,4′,4″-tris-(N-(naphthylen-2-yl)-N-phenylamine)triphenylamine (2-TNATA)), a hole transport layer 108 on the hole injection layer 106 (including N,N′-di-[(1-naphthyl)-N,N′-diphenyl]-1,1′-biphenyl)-4,4′-diamine (α-NPD)), an emission layer 110 on the hole transport layer 108 (obtained by doping one of Compound 1, Compound 5, Compound 7, Compound 9, Compound 14, Compound 22, Compound 23, Compound 24, Compound 25, and the comparative compound at a 3% concentration into a host material including 9,10-di(2-naphtyl)anthracene (ADN)), an electron transport layer 112 on the emission layer 110 (including tris(8-hydroxyquinolinato)aluminum (Alq₃)), an electron injection layer 114 on the electron transport layer 112 (including LiF), and a negative electrode 116 on the electron injection layer 114 (formed using Al). The thickness of the positive electrode 104 was about 150 nm, the thickness of the hole injection layer 106 was about 60 nm, the thickness of the hole transport layer was about 30 nm, the thickness of the emission layer 110 was about 25 nm, the thickness of the electron transport layer 112 was about 25 nm, the thickness of the electron injection layer 114 was about 1 nm, and the thickness of the negative electrode 116 was about 100 nm.

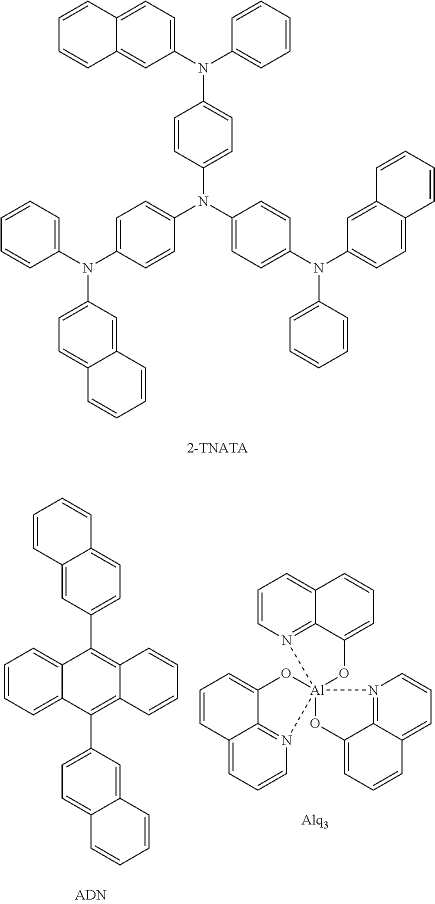

Electricity was provided to the organic EL device 100 from a power source through the positive electrode 104 and the negative electrode 116. The current efficiency of the organic EL device was measured when using Compound 1, Compound 5, Compound 7, Compound 9, Compound 14, Compound 22, Compound 23, Compound 24, Compound 25, or the comparative compound as the light-emitting material (dopant material) of the emission layer 108. The results are illustrated in the following Table 2. In this case, the current efficiency was measured at 10 mA/cm2.

TABLE 2

| Device properties | | Light-emitting efficiency (lm/W) |
|---|---|---|
| Example 1 | Compound 1 | 2.50 |
| Example 2 | Compound 5 | 2.48 |
| Example 3 | Compound 7 | 2.54 |
| Example 4 | Compound 9 | 2.72 |
| Example 5 | Compound 14 | 2.41 |
| Example 6 | Compound 22 | 2.59 |
| Example 7 | Compound 23 | 2.79 |
| Example 8 | Compound 24 | 2.39 |
| Example 9 | Compound 25 | 2.84 |
| Comparative | 6,12- | 1.64 |
| Example | bis(diphenylamino)chrysene | |

As may be seen in Table 2, the organic EL device using the 5-aminothiazole derivative, i.e., including Compound 1, Compound 5, Compound 7, Compound 9, Compound 14, Compound 22, Compound 23, Compound 24, or Compound 25, as the light-emitting material exhibited higher light-emitting efficiency when compared to the organic EL device using another amine-based and phosphorescent blue dopant material, i.e., 6,12-bis(diphenylamino)chrysene.

Therefore, when the 5-aminothiazole derivative of an embodiment is used as the light-emitting material of the emission layer of an organic EL device, the light-emitting efficiency of the organic EL device may be improved.

In the above-described embodiments, the 5-aminothiazole derivative was used as the light-emitting material of a passive type organic EL device. The 5-aminothiazole derivative according to an embodiment may be used as the light-emitting material of, e.g., an active type organic EL device, and may improve the light-emitting efficiency of the active type organic EL device.

The organic EL device using the 5-aminothiazole derivative according to an embodiment as the light-emitting material may be used in an organic EL display device or an illumination system.

By way of summation and review, in an organic EL device, high efficiency of the organic EL device may be desirable. To realize the high efficiency of the organic EL device, various light-emitting materials may be considered. For example, improvement of the light-emitting efficiency of a blue light-emitting material may be desirable because of the low light-emitting efficiency, when compared to a red light-emitting material and a green light-emitting material.

An embodiment may provide an organic EL material for realizing high efficiency.

The organic EL device according to an embodiment may exhibit improved light-emitting efficiency.

The organic EL device according to an embodiment may exhibit improved light-emitting efficiency in a blue region.

According to an embodiment, an organic EL material may include a combination of a compound having Formula (1) and another compound, e.g., a substituted or unsubstituted naphthalene derivative, anthracene derivative, phenanthrene derivative, pyrene derivative, triphenylene derivative, chrysene derivative, perylene derivative and fluorene derivative or a combination of the compound having Formula (1) and the substituted or unsubstituted anthracene derivative or substituted or unsubstituted pyrene derivative. An emission layer of the organic EL device may include the organic EL material, thereby realizing the improvement of light-emitting efficiency.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic electroluminescence (EL) device comprising an organic EL material represented by the following Formula (1): 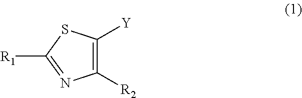
wherein:
R₁ is selected from the group of a branched or cyclic alkyl group having 3 to 20 carbon atoms, an aryl group having 6 to 24 carbon atoms, and a heteroaryl group having 6 to 24 carbon atoms, each being unsubstituted or substituted with at least one substituent selected from the group of a halogen atom, a hydroxyl group, a lower alkyl group, a lower alkoxy group, and a lower haloalkyl group,
R₂ is a substituted or unsubstituted aryl group or a substituted or unsubstituted heteroaryl group, the substituted aryl group or substituted heteroaryl group being substituted with at least one substituent selected from the group of a halogen atom, a hydroxyl group, a lower alkyl group, a lower alkoxy group, and a lower haloalkyl group, and
Y is a substituent represented by the following Formula (2), 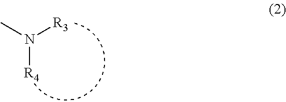
wherein, in Formula 2, R₃ and R₄ are each independently selected from the group of a linear or branched alkyl group having 1 to 20 carbon atoms, a cyclic alkyl group having 3 to 20 carbon atoms, an aryl group having 6 to 24 carbon atoms, and a heteroaryl group having 6 to 24 carbon atoms, each being unsubstituted or substituted with at least one substituent selected from the group of a halogen atom, a hydroxyl group, a lower alkyl group, a lower alkoxy group, a lower haloalkyl group, an aryl group, and a heteroaryl group.

2. The organic EL device as claimed in claim 1, wherein R₃ and R₄ are bound together and form a heterocycle with a nitrogen atom (N) in the substituent represented by Formula (2).

3. The organic EL device as claimed in claim 1, wherein R₃ and R₄ are separate from one another.

4. The organic EL device as claimed in claim 1, wherein the organic EL material represented by above Formula (1) is a light-emitting material of the organic EL device.

5. The organic EL device as claimed in claim 4, wherein the light-emitting material is a blue light-emitting material.

6. The organic EL device as claimed in claim 4, wherein the light-emitting material is included in an emission layer along with a condensed polycyclic hydrocarbon derivative.

7. The organic EL device as claimed in claim 6, wherein the condensed polycyclic hydrocarbon derivative is one of a substituted or unsubstituted naphthalene derivative, a substituted or unsubstituted anthracene derivative, a substituted or unsubstituted phenanthrene derivative, a substituted or unsubstituted pyrene derivative, a substituted or unsubstituted triphenylene derivative, a substituted or unsubstituted chrysene derivative, a substituted or unsubstituted perylene derivative, or a substituted or unsubstituted fluorene derivative.

8. The organic EL device as claimed in claim 7, wherein the condensed polycyclic hydrocarbon derivative is the substituted or unsubstituted anthracene derivative or the substituted or unsubstituted pyrene derivative.

9. The organic EL device as claimed in claim 6, wherein the condensed polycyclic hydrocarbon derivative is a host and the organic EL material represented by the above Formula (1) is a dopant.
